(19) United States
(12) Patent Application Publication
(10) Pub. No.: US 2026/0271236 A1
(43) Pub. Date: Sep. 10, 2026

(54) SERVER

(71) Applicants: INVENTEC (PUDONG) TECHNOLOGY CORPORATION, Shanghai (CN); INVENTEC CORPORATION, Taipei City (TW)

(72) Inventors: Guoping WU, Shanghai (CN); Lian-Fei ZHANG, Shanghai (CN)

(73) Assignees: INVENTEC (PUDONG) TECHNOLOGY CORPORATION, Shanghai (CN); INVENTEC CORPORATION, Taipei City (TW)

(21) Appl. No.: 19/219,139

(22) Filed: May 27, 2025

(30) Foreign Application Priority Data
Mar. 7, 2025 (CN) 202510267976.3

(51) Int. Cl. H05K 7/20

(52) U.S. Cl. CPC H05K 7/2039; H05K 7/20145; H05K 7/20727; H05K 7/20809

(57) ABSTRACT

A server includes a casing, a circuit board, at least one primary heat source, at least one secondary heat source and at least one radiator. The casing has a bottom plate. The circuit board is disposed on the bottom plate, and has a bottom surface and a top surface facing away from each other. The bottom surface faces toward the bottom plate. The at least one primary heat source is disposed on the bottom surface. The at least one secondary heat source is disposed on the top surface. An amount of heat generated by the at least one secondary heat source is less than an amount of heat generated by the at least one primary heat source. The at least one radiator is disposed on the bottom plate, and is thermally coupled to the at least one primary heat source.

### CROSS-REFERENCE TO RELATED APPLICATIONS

This non-provisional application claims priority under 35 U.S.C. § 119(a) on Patent Application No(s). 202510267976.3 filed in CHINA, on March 7, 2025, the entire contents of which are hereby incorporated by reference.

### BACKGROUND OF THE INVENTION

### Technical Field of the Invention

The invention relates to a server, more particularly to a server whose primary heat source is disposed on a bottom surface of a circuit board.

### Description of the Related Art

With the arrival of the big data era and the continuous development of cloud technology, the requirements for high-end servers are higher than ever, and the amount of the data needing to be processed is increasing. Accordingly, the density of heat transferring at the servers rapidly increases, and heat generated thereby also increases massively. Therefore, the issue of heat dissipation needs to be improved urgently.

Generally, the servers can be cooled by air cooling system. However, the cooling efficiency for electronic components with high power disposed in the servers is insufficient, thereby adversely affecting the operation of the servers. Therefore, improving the cooling efficiency for the electronic components with high power disposed in the servers is one of the key issues that researchers need to address.

### SUMMARY OF THE INVENTION

The invention provides a server for improving the cooling efficiency for heat sources disposed in the server.

One embodiment of the invention provides a server including a casing, a circuit board, at least one primary heat source, at least one secondary heat source and at least one radiator. The casing has a bottom plate. The circuit board is disposed on the bottom plate, and has a bottom surface and a top surface facing away from each other. The bottom surface faces toward the bottom plate. The at least one primary heat source is disposed on the bottom surface. The at least one secondary heat source is disposed on the top surface. An amount of heat generated by the at least one secondary heat source is less than an amount of heat generated by the at least one primary heat source. The at least one radiator is disposed on the bottom plate, and is thermally coupled to the at least one primary heat source.

According to the server disclosed in the above embodiment, the at least one primary heat source and the at least one secondary heat source are disposed on the bottom surface and the top surface of the circuit board, respectively, such that the at least one primary heat source is located away from the at least one secondary heat source to define a cooling area dedicated to the at least one primary heat source. Therefore, the at least one primary heat source can be cooled with a larger space to prevent the heat generated by the at least one primary heat source and the at least one secondary heat source from being difficult to be dissipated by accumulated in one place in a concentrate manner. Accordingly, the cooling efficiency for the at least one primary heat source disposed in the server can be improved.

### BRIEF DESCRIPTION OF THE DRAWINGS

The invention will become more fully understood from the detailed description given herein below and the accompanying drawings which are given by way of illustration only and thus are not limitative of the invention and wherein:

FIG. 1 is a perspective view of a server in accordance with an embodiment of the invention;

FIG. 2 is an exploded view of the server in FIG. 1;

FIG. 3 is a cross-sectional view of the server in FIG. 1;

FIG. 4 is a perspective view of a radiator of the server in FIG. 1; and

FIG. 5 is a perspective view of the radiator of the server in FIG. 1 omitting a thermally conductive substrate.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

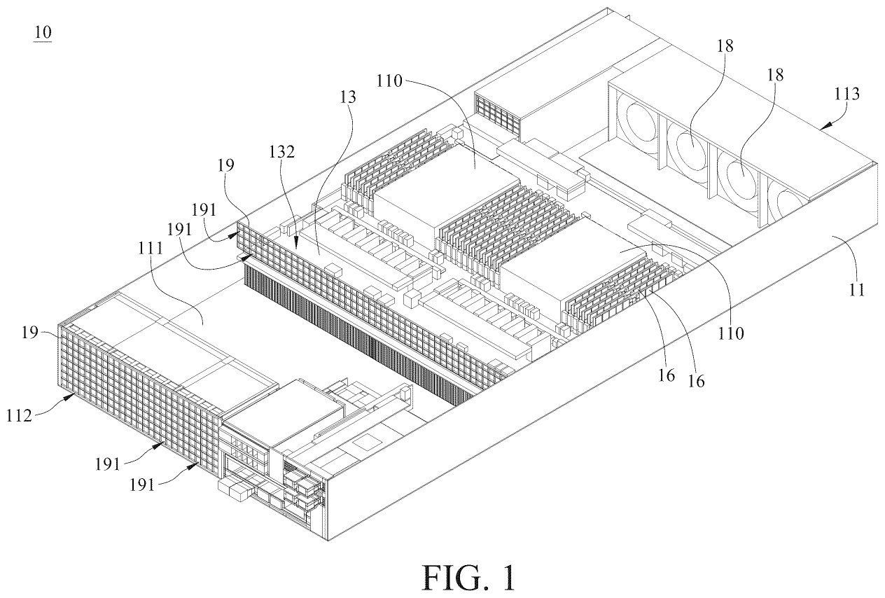

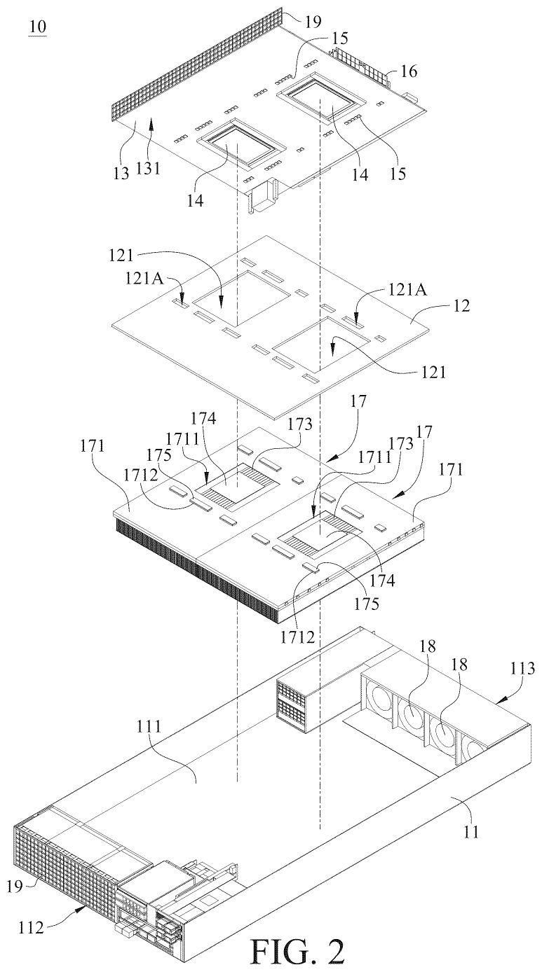

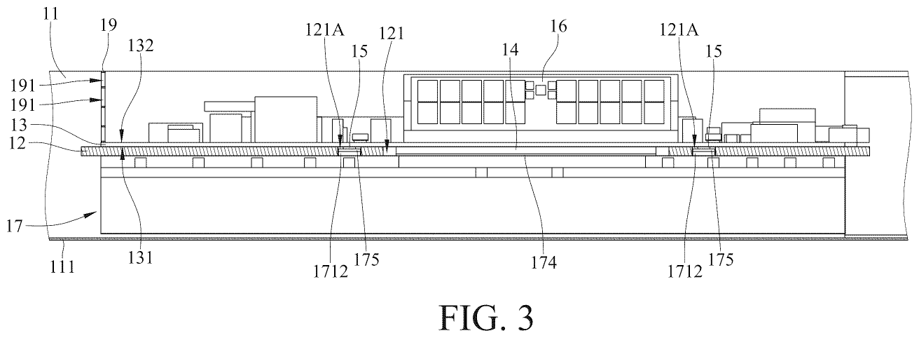

Please refer to FIG. 1 to FIG. 3, where FIG. 1 is a perspective view of a server 10 in accordance with an embodiment of the invention, FIG. 2 is an exploded view of the server 10 in FIG. 1, and FIG. 3 is a cross-sectional view of the server 10 in FIG. 1.

In this embodiment, the server 10 includes a casing 11, a tray 12, a circuit board 13, a plurality of primary heat sources 14, a plurality of vice heat sources 15, a plurality of secondary heat sources 16, a plurality of radiators 17 and a plurality of fans 18. The casing 11 has a bottom plate 111. The tray 12 is disposed in the casing 11, and supports the circuit board 13. The circuit board 13 has a bottom surface 131 and a top surface 132 facing away from each other. The bottom surface 131 faces toward the bottom plate 111.

The primary heat sources 14 are, for example, CPU chips. The vice heat sources 15 are, for example, electronic components such as VR MOS chips. The primary heat sources 14 and the vice heat sources 15 are disposed on the bottom surface 131. The secondary heat sources 16 are, for example, electronic components with low power such as DIMMs and capacitors and inductors that are high, and are disposed on the top surface 132. That is, the primary heat sources 14, the vice heat sources 15 and the secondary heat sources 16 are disposed on opposite sides of the circuit board 13, respectively, which means that the primary heat sources 14, the vice heat sources 15 and the secondary heat sources 16 are disposed in layers. The primary heat sources 14 and the vice heat sources 15 are disposed on a bottom side (lower layer) of the circuit board 13. An amount of heat generated by the secondary heat sources 16 is less than an amount of heat generated by the primary heat sources 14. The radiators 17 are disposed on the bottom plate 111, and are thermally coupled to the primary heat sources 14 and the vice heat sources 15, respectively.

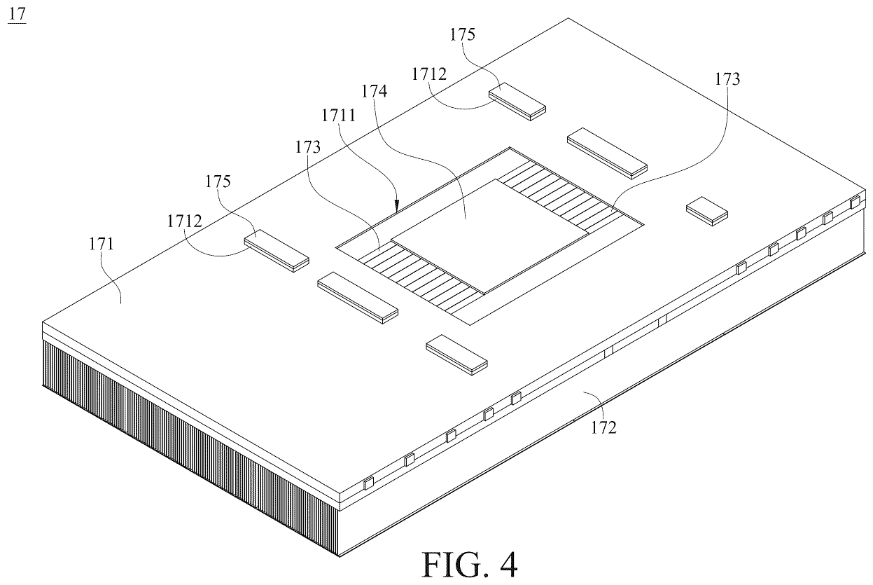

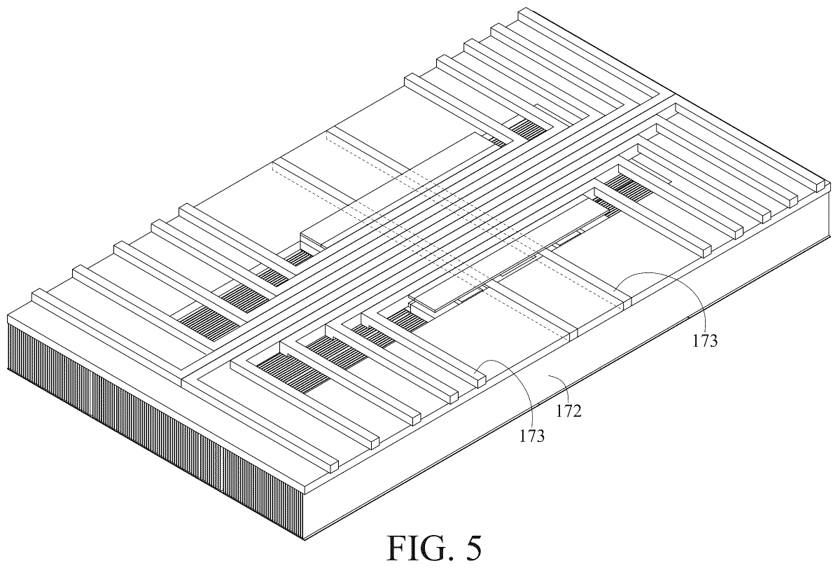

Please refer to FIG. 1 to FIG. 5, where FIG. 4 is a perspective view of the radiator 17 of the server 10 in FIG. 1, and FIG. 5 is a perspective view of the radiator 17 o fthe server 10 in FIG. 1 omitting a thermally conductive substrate 171.

In detail, each of the radiators 17 includes the thermally conductive substrate 171, a heat sink 172, a plurality of heat pipes 173, a plurality of first thermally conductive members 174 and a plurality of second thermally conductive members 175. The heat sink 172 and the heat pipes 173 are disposed on the thermally conductive substrate 171. The heat pipes 173 are disposed in, for example, layers on the thermally conductive substrate 171, but the invention is not limited thereto. The tray 12 has a plurality of first openings 121 and 121A, and the thermally conductive substrate 171 has a plurality of second openings 1711. The second openings 1711 correspond to the first openings 121, respectively. The primary heat sources 14 are disposed through the first openings 121 and the second openings 1711, and are thermally coupled to the heat pipes 173.

In this embodiment, the thermally conductive substrate 171 has a plurality of protrusions 1712. The vice heat sources 15 are disposed through the first openings 121A, and are thermally coupled to the protrusions 1712, respectively. Since a height of the vice heat sources 15 is less than a height of the primary heat sources 14, the thermal coupling between the radiators 17 and the vice heat sources 15 can be realized by the protrusions 1712.

For example, the first thermally conductive members 174 are thermal interface materials such as thermal adhesives, and are thermally coupled between the primary heat sources 14 and the heat pipes 173. For example, the second thermally conductive members 175 are, thermal pads, and are thermally coupled between the vice heat sources 15 and the protrusions 1712.

The casing 11 has an inlet 112 and an outlet 113. The inlet 112 is in fluid communication with the outlet 113. The inlet 112 is configured for a cooling airflow to flow into the casing 11 so as to cool the primary heat sources 14 and the secondary heat sources 16, and the outlet 113 is configured for the cooling airflow to flow out of the casing 11. The fans 18 are, for example, in the form of exhaust fans, and are disposed at the outlet 113. When the cooling airflow flows into the casing 11 from the inlet 112, the cooling airflow can flow through the primary heat sources 14 and the secondary heat sources 16 to cool the same. Then, the cooling airflow flows out of the casing 11 from the outlet 113 via the fans 18.

In this embodiment, the primary heat sources 14 and the secondary heat sources 16 are disposed on the bottom surface 131 and the top surface 132 of the circuit board 13, respectively, such that the primary heat sources 14 are located away from the secondary heat sources 16 to define a cooling area dedicated to the primary heat sources 14. Therefore, the primary heat sources 14 can be cooled with a larger space to prevent the heat generated by the primary heat sources 14 and the secondary heat sources 16 from being difficult to be dissipated by accumulated in one place in a concentrate manner. Accordingly, the cooling efficiency for the primary heat sources 14 disposed in the server 10 can be improved.

In this embodiment, the server 10 may include two limiting plates 19. The limiting plates 19 are disposed between the inlet 112 and the secondary heat sources 16. In detail, one of the limiting plates 19 is disposed on a part of the casing 11 located close to the inlet 112, and the other limiting plate 19 is disposed on the top surface 132 of the circuit board 13. The limiting plates 19 are made of, for example, metal.

Each of the limiting plates 19 has a plurality of limiting holes 191. The limiting holes 191 are configured to limit the amount of the cooling airflow flowing through the secondary heat sources 16. In addition, a part of the cooling airflow can be redirected to the primary heat sources 14 by the limiting plates 19. Upon, the primary heat sources 14 require the higher cooling capacity than the secondary heat sources 16, with the help of the limiting plates 19, additional amount of the cooling airflow are distributed to the primary heat sources 14, thereby improving the cooling capacity for the primary heat sources 14.

In this embodiment, the server 10 may include a plurality of guiding members 110. The guiding members 110 are, for example, blocks, and are disposed on the top surface 132 of the circuit board 13. The guiding members 110 can block the cooling airflow and change the flowing path of the cooling airflow so as to guide the cooling airflow to flow toward the secondary heat sources 16 in a concentrated manner.

In this embodiment, the server 10 includes the tray 12, and the tray 12 supports the circuit board 13, but the invention is not limited thereto. In other embodiments, the server may not include the tray, and the circuit board is disposed on, for example, the bottom plate.

In this embodiment, there are multiple primary heat sources 14, multiple vice heat sources 15, multiple secondary heat sources 16, multiple radiators 17, multiple first openings 121 and 121A and multiple second openings 1711, but the invention is not limited thereto. In other embodiments, there may be one primary heat source, one vice heat source, one secondary heat source, one radiator merely, one first opening merely, and one second opening merely.

In this embodiment, each of the radiators 17 includes multiple heat pipes 173, but the invention is not limited thereto. In other embodiments, each of the radiators may include one heat pipe merely.

In this embodiment, each of the radiators 17 includes the heat pipes 173, but the invention is not limited thereto. In other embodiments, the heat pipes may be replaced with vapor chambers.

In this embodiment, the thermally conductive substrate 171 has multiple protrusions 1712, but the invention is not limited thereto. In other embodiments, the thermally conductive substrate may have one protrusion merely, as long as the quantity of the protrusion corresponds to the quantity of the vice heat sources.

In this embodiment, the server 10 includes multiple first thermally conductive members 174 and multiple second thermally conductive members 175, but the invention is not limited thereto. In other embodiments, the server may include one first thermally conductive member and one second thermally conductive member merely.

In this embodiment, the server 10 includes two limiting plates 19. One of the limiting plates 19 is disposed on the part of the casing 11 located close to the inlet 112, and the other limiting plate 19 is disposed on the top surface 132 of the circuit board 13, but the invention is not limited thereto. In other embodiments, the server may include one limiting plate merely, and the limiting plate may be disposed on the part of the casing located close to the inlet or the top surface of the circuit board, or the server may include more than two limiting plates.

In this embodiment, the server 10 includes multiple fans 18, but the invention is not limited thereto. In other embodiments, the server may include one fan merely.

According to the server disclosed in the above embodiment, the primary heat sources and the secondary heat sources are disposed on the bottom surface and the top surface of the circuit board, respectively, such that the primary heat sources are located away from the secondary heat sources to define a cooling area dedicated to the primary heat sources. Therefore, the primary heat sources can be cooled with a larger space to prevent the heat generated by the primary heat sources and the secondary heat sources from being difficult to be dissipated by accumulated in one place in a concentrate manner. Accordingly, the cooling efficiency for the primary heat sources disposed in the server can be improved.

It will be apparent to those skilled in the art that various modifications and variations can be made to the invention. It is intended that the specification and examples be considered as exemplary embodiments only, with the scope of the invention being indicated by the following claims.

What is claimed is:

1. A server, comprising:
a casing, having a bottom plate;
a circuit board, disposed on the bottom plate and having a bottom surface and a top surface facing away from each other, wherein the bottom surface faces toward the bottom plate;
at least one primary heat source, disposed on the bottom surface;
at least one secondary heat source, disposed on the top surface, wherein an amount of heat generated by the at least one secondary heat source is less than an amount of heat generated by the at least one primary heat source; and
at least one radiator, disposed on the bottom plate and thermally coupled to the at least one primary heat source.

2. The server according to claim 1, further comprising a tray, wherein the tray is disposed in the casing, and supports the circuit board.

3. The server according to claim 2, wherein the tray has at least one first opening, and the at least one primary heat source is disposed through the at least one first opening.

4. The server according to claim 3, wherein the at least one radiator comprises a thermally conductive substrate, a heat sink and at least one heat pipe, the heat sink and the at least one heat pipe are disposed on the thermally conductive substrate, the thermally conductive substrate has a second opening, the second opening corresponds to the at least one first opening, the at least one primary heat source is disposed through the second opening, and is thermally coupled to the at least one heat pipe.

5. The server according to claim 4, further comprising at least one vice heat source, wherein the at least one vice heat source is disposed on the bottom surface, the thermally conductive substrate has at least one protrusion, and the at least one vice heat source is thermally coupled to the at least one protrusion.

6. The server according to claim 5, wherein the at least one radiator further comprises at least one first thermally conductive member and at least one second thermally conductive member, the at least one first thermally conductive member is thermally coupled between the at least one primary heat source and the at least one heat pipe, and the at least one second thermally conductive member is thermally coupled between the at least one vice heat source and the at least one protrusion.

7. The server according to claim 1, wherein the casing further has an inlet and an outlet, the inlet is configured for a cooling airflow to flow into the casing, and the outlet is configured for the cooling airflow to flow out of the casing.

8. The server according to claim 7, further comprising at least one limiting plate, wherein the at least one limiting plate is disposed between the inlet and the at least one secondary heat source, and has a plurality of limiting holes, and the plurality of limiting holes are configured to limit the amount of the cooling airflow flowing through the at least one secondary heat source.

9. The server according to claim 7, further comprising at least one fan, wherein the at least one fan is disposed at the outlet.

10. The server according to claim 1, further comprising at least one guiding member, wherein the at least one guiding member is disposed on the top surface to guide a cooling airflow to flow toward the at least one secondary heat source.
